(19) United States
(12) Patent Application Publication
(10) Pub. No.: US 2018/0152148 A1
(43) Pub. Date: May 31, 2018

(54) DOHERTY AMPLIFIER

(71) Applicant: SUMITOMO ELECTRIC DEVICE INNOVATIONS, INC., Yokohama-shi (JP)

(72) Inventor: James Wong, Surrey (GB)

(21) Appl. No.: 15/825,954

(22) Filed: Nov. 29, 2017

Related U.S. Application Data
(60) Provisional application No. 62/427,929, filed on Nov. 30, 2016.

(51) Int. Cl. H03F 1/02; H03F 3/19; H03F 1/56

(52) U.S. Cl. CPC H03F 1/0288; H03F 3/19; H03F 2200/423; H03F 2200/192; H03F 2200/451; H03F 1/56

(57) ABSTRACT

A symmetrical Doherty amplifier having a back-off region greater than 6 dB is disclosed. The Doherty amplifier includes a transmission line provided in downstream the carrier amplifier and another transmission line provided in downstream the combining node where outputs of the carrier amplifier and the peak amplifier are combined. The former transmission line has characteristic impedance greater than the load impedance, while, the latter transmission line has characteristic impedance greater than the load impedance divided by square-root of 2.

### CROSS REFERENCE TO RELATED APPLICATION

This application claims the priority under 35 U.S.C. § 119 of U.S. Provisional Application Ser. No. 62/427,929, filed on Nov. 30, 2016, the contents of which is relied upon and incorporated herein by reference in its entirety.

### BACKGROUND OF THE INVENTION

### 1. Field of the Invention

The present invention relates to a Doherty amplifier, in particular, the invention relates to a symmetrical Doherty amplifier that includes a carrier amplifier and a peak amplifier having arrangements same to each other and expands the back-off range thereof.

### 2. Related Background Arts

Digitally modulated signals applicable to a radio communication such as a mobile telephone need considerable instantaneous power compared with average power. A transmitter for outputting such modulated signals is inevitably requested to be operable as securing a large back-off range from saturation power. A Doherty amplifier has been widely installed within such a communication system that secures a wide back-off range in order to enhance efficiency of amplifying a microwave signal. A symmetrical Doherty amplifier that implements two amplifiers having saturation power same to each other shows the maximum efficiency at the back-off range 6 dB below the saturation power. On the other hand, a digitally modulated signal implemented within the base station of the radio communication system often shows 8 dB difference between the peak power and the average power. Accordingly, ordinary symmetric Doherty amplifier inevitable shows lesser efficiency when implemented within such system.

In order to enhance the efficiency at the back-off range or expand the back-off range, for instance, greater than 6 dB, a system often implements an asymmetrical arrangement in a Doherty amplifier. That is, a carrier amplifier and a peak amplifier have respective saturation power different from each other. However, such an asymmetrical Doherty amplifier inevitably accompanies with degraded AM-AM distortion. Also, because the input signal is necessary to be divided unevenly to the respective amplifiers, the input power for the carrier amplifier decreases and the total power gain also decreases compared with the symmetrical Doherty amplifier.

A Japanese Patent laid open No. JP-2006-166141A has disclosed a Doherty amplifier having a carrier amplifier accompanied with an impedance converter, a peak amplifier also accompanied with another impedance converter, a combiner, and a final impedance converter. The Doherty amplifier disclosed therein widens the back-off range by varying a conversion ratio of the impedance converter set downstream the peak amplifier and that of the impedance converter set downstream the carrier amplifier.

### SUMMARY OF INVENTION

An aspect of the present invention relates to a Doherty amplifier that amplifies a radio frequency (RF) signal with a wavelength of A. The Doherty amplifier includes a carrier amplifier and a peak amplifier. The carrier amplifier operates in a whole range of output power of the Doherty amplifier, while, the peak amplifier operates in a back-off region of the output power. The Doherty amplifier includes an input splitter, a firs transmission line, and a second transmission line. The input splitter evenly splits the RF signal for the carrier amplifier and the peak amplifier. A portion of the RF signal provided to the peak amplifier is delayed by 90° with respect another portion of the RF signal provided for the carrier amplifier. The first transmission line has one end connected to an output of the carrier amplifier and another end. The first transmission line has an electrical length of λ/4. The second transmission line has one end and another end. The second transmission line also has an electrical length of λ/4. The one end of the second transmission line is connected to an output of the peak amplifier and the another end of the first transmission line. The another end of the second transmission line is connected to a load of the Doherty amplifier, where the load has load impedance Z₀. A feature of the Doherty amplifier of the invention is that the first transmission line has characteristic impedance greater than the load impedance Z₀, and the second transmission line has characteristic impedance greater than the load impedance Z₀ divided by a square root of 2.

### BRIEF DESCRIPTION OF THE DRAWINGS

The invention will now be described by way of example only with reference to the accompanying drawings in which:

FIG. 1 schematically illustrates a fundamental configuration of a conventional symmetrical Doherty amplifier;

FIG. 2 schematically illustrates a configuration of a symmetrical Doherty amplifier according to the present invention, where the Doherty amplifier shown in FIG. 2 expands the back-off range;

FIG. 3 shows a functional block diagram of the Doherty amplifier according embodiment of the present invention;

FIG. 4 shows efficiency against the output power of the Doherty amplifier shown in FIG. 3; and

FIG. 5A shows gain behaviors against the output power for frequencies 2.6 to 2.7 GHz of the Doherty amplifier shown in FIG. 3, and FIG. 5B shows behaviors of the drain current of the carrier amplifier and that of the peak amplifier.

### DESCRIPTION OF EMBODIMENT

Next, some examples of a Doherty amplifier according to the present invention will be described as referring to accompanying drawings. In the explanation of the drawings, numerals or symbols same with or similar to each other will refer to elements same with or similar toe each other without duplicating explanations.

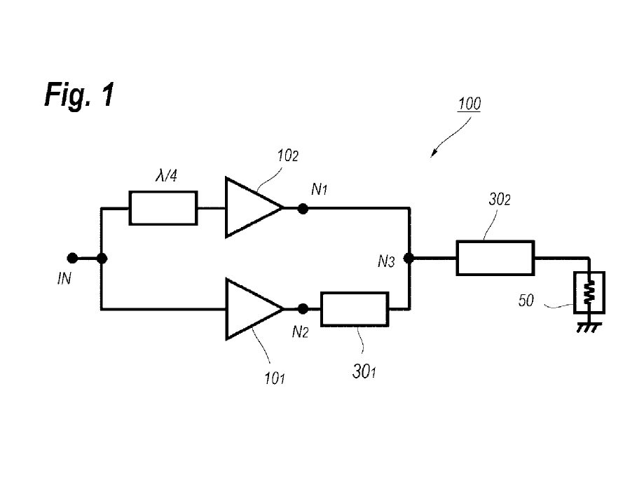

FIG. 1 shows a functional block diagram of a symmetrical Doherty amplifier that receives an input radio frequency (RF) signal in an input terminal IN. The RF signal input therein is split into two portions, one of which directly enters within a carrier amplifier 10₁, while, the other indirectly enters within a peak amplifier 10₂ through a transmission line that has an electrical length of λ/4, where λ is a wavelength of the RF signal. In a symmetrical Doherty amplifier, the carrier amplifier 10₁ and the peak amplifier 10₂ may be a type of filed effect transistor (FET) having arrangements substantially same to each other, for instance, such as gate lengths, gate widths, trans-conductance gm, and so on. Because the peak amplifier 10₂ receives a portion of the RF signal through the transmission line with the electrical length of λ/4, the RF signal entering the peak amplifier 10₂ has a phase delayed by 90° from the phase of the RF signal inputting the carrier amplifier 10₁.

The carrier amplifier 10₁ provides an output thereof through a transmission line 30₁, while, the peak amplifier 10₂ provides an output thereof directly to a combining node N₃. A transmission line 30₂ may provide thus combined two outputs coming from the carrier amplifier 10₁ and the peak amplifier to a load 50. Because the output of the carrier amplifier 10₁ is combined with the output of the peak amplifier 10₂ through the transmission line 30₁ at the combining node N₃, two outputs may align the respective phases at the combining node N₃. The peak amplifier 10₂ is generally biased in the class B or in the class C, which means the peak amplifier 10₂ turns off when the input signal is small in amplitude thereof. On the other hand, because the carrier amplifier 10₁ is biased in the class A, or in the class AB, the carrier amplifier 10₁ operates in a whole range of the input power of the input RF signal, that is, the carrier amplifier 10₁ turns on even when the input RF signal is small. The peak amplifier 10₂ may turn on when the carrier amplifier 10₁ saturates and saturate at a level 6 dB greater than the saturation level of the carrier amplifier 10₁. A region where both the carrier amplifier 10₁ and the peak amplifier 10₂ operate is sometimes called as a back-off. Thus, a symmetrical Doherty amplifier 100 may enhance the saturated output power by 6 dB from the saturation level of the carrier amplifier 10₁.

A symmetrical Doherty amplifier 100 will be further described in an operation thereof. Impedance at the combining node N₃ should become (Z₀/√2)²/Z₀=Z₀/2, where Z₀ is the load impedance and the transmission line 30₂ has an electrical length of λ/4 and characteristic impedance thereof is set to be Z₀/√2, λ is a wavelength of a radio frequency (RF) signal subject to the Doherty amplifier 100. When the RF signal in amplitude thereof is small where only the carrier amplifier 10₁ operates and the peak amplifier 10₂ turns off, the output impedance of the peak amplifier 10₂ seeing from the combining node N₃ may be regarded as an open-circuit and the transmission line 30₁ has the characteristic impedance of Z₀. Then, the impedance seeing the load 50 from the output of the carrier amplifier 10₁ at the node N₂ becomes Z₀²/(Z₀/2)=2*Z₀. When the transmission lines, 30₁ and 30₂, have characteristic impedance of 50 and 25Ω, respectively, and the load impedance Z₀ is set to be 50Ω, the impedance seeing the load 50 from the carrier amplifier 10₁ becomes 100Ω.

When the carrier amplifier 10₁ and the peak amplifier 10₂ both turn on at the saturation thereof, and the impedance seeing the load 50 from the carrier amplifier 10₁ and the peak amplifier 10₂ are each preferably set to be 50Ω. The impedance at the combining node N₃ may be given by a parallel connection of the impedance of the peak amplifier 10₂ and the impedance of the carrier amplifier 10₁ transformed by the transmission line 30₁ with the characteristic impedance of 50Ω. That is the impedance combined at the combining node N₃ becomes 50//50=25Ω. That is, setting the characteristic impedance of the transmission lines, 30₁ and 30₂, to be Z₀ and Z₀/2, respectively, the load impedance for the carrier amplifier 10₁ may be regarded as 2*Z₀ when only the carrier amplifier 10₁ operates when the output power is below the back-off region, while, the load impedance for the carrier amplifier 10₁ and that for the peak amplifier 10₂ each become Z₀ when both amplifiers, 10₁ and 10₂, saturate at the back-off region. In the back-off region, the load impedance for the carrier amplifier 10₁ gradually decreases from 2*Z₀ to Z₀ and that for the peak amplifier 10₂ drastically decreases from a large value to Z₀ as the output power increases.

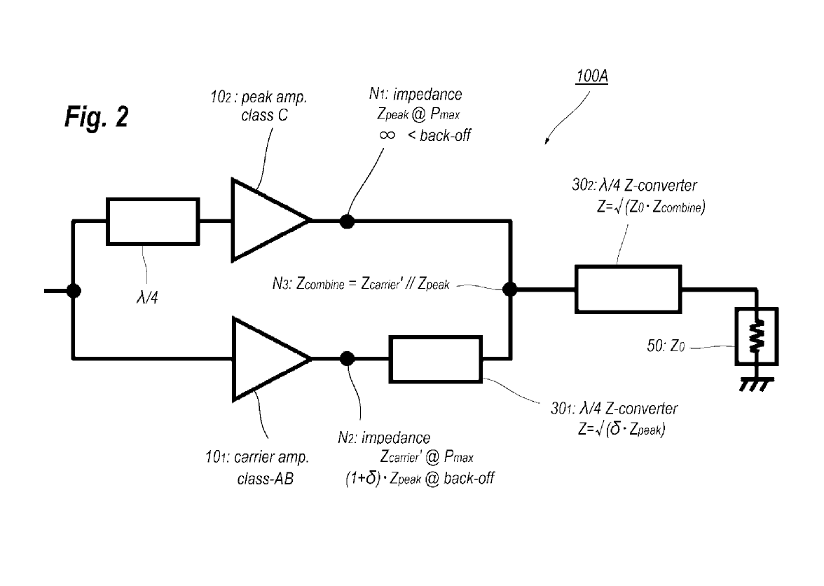

FIG. 2 schematically illustrates a functional block diagram of a Doherty amplifier 100A according to embodiment of the present invention. The Doherty amplifier 100A shown in FIG. 2 has a feature that the transmission line put in downstream the carrier amplifier 10₁ has characteristic impedance Z₀′ that is different from the load impedance Z₀ and the other transmission line 30₂ has characteristic impedance different from a conventional value of Z₀/√2. Next, a theoretical background of the Doherty amplifier 100A will be first described.

First setting the output back-off OBO as follows in a logarithmic expression:

OBO=P_{PEAK}−P_{AVE}, (1)

where P_{PEAK} and P_{AVE} have units of dBm and correspond to the total power when the carrier amplifier 10₁ and the peak amplifier 10₂ both generate largest power and the power when only the carrier amplifier 10₁ generates the largest power, that is, the power when the peak amplifier 10₂ turns on.

We convert the equation (1) above using a linear parameter δ of:

δ=10̂(OBO/20)−1. (2)

The combined impedance at the combining node N₃, which is denoted as Z_{COMBINE} is given by a parallel impedance of the output impedance of the carrier amplifier 10₁ converted by the transmission line 30₁, which is denoted as Z_{CARRIER}′, and the output impedance Z_{PEAK} of the peak amplifier 10₂. A conventional Doherty amplifier generally equalizes the converted impedance Z_{CARRIER}′ of the carrier amplifier 10₁ with the output impedance Z_{PEAK} of the peak amplifier 10₂ when two amplifiers, 10₁ and 10₂, generate the largest power, and the combined impedance Z_{COMBINE} may be given by Z_{COMBINE}=Z_{CARRIER}′//Z_{PEAK}. On the other hand, the Doherty amplifier 100A of the embodiment has the combined impedance Z_{COMBINE} given by:

Z_{COMBINE}=δ×Z_{PEAK}/(1+δ), (3)

because the embodiment induces the non-linear parameter δ. That is, the peak amplifier 10₂ generates power greater than the power generated by the carrier amplifier 10₁ when the Doherty amplifier 100A generates the largest power.

Because the combined impedance Z_{COMBINE} is a parallel impedance of the output impedance of the carrier amplifier 10₁ converted by the transmission line 30₁, namely Z_{CARRIER}′, and the output impedance Z_{PEAK} of the peak amplifier 10₂, the converted impedance Z_{CARRIER}′ is given by:

Z_{CARRIER}′=Z_{COMBINE}×Z_{PEAK}/(Z_{PEAK}−Z_{COMBINE}). (4)

That is, the converted impedance Z_{CARRIER}′ for the carrier amplifier 10₁ exceeds the output impedance ZPEAK of the peak amplifier 10₂, namely, Z_{CARRIER}′>Z_{PEAK}, when the non-linear parameter δ is greater than unity.

Then, setting the characteristic impedance, Z₃₀₁ and Z₃₀₂, of the transmission lines, 30₁ and 30₂ to be:

Z₃₀₁=√δ×Z_{PEAK}, and

Z₃₀₂=√(Z₀×Z_{COMBINE}), (5)

respectively, the symmetrical Doherty amplifier 100A may expand the back-off region greater than 6 dB.

### Embodiment

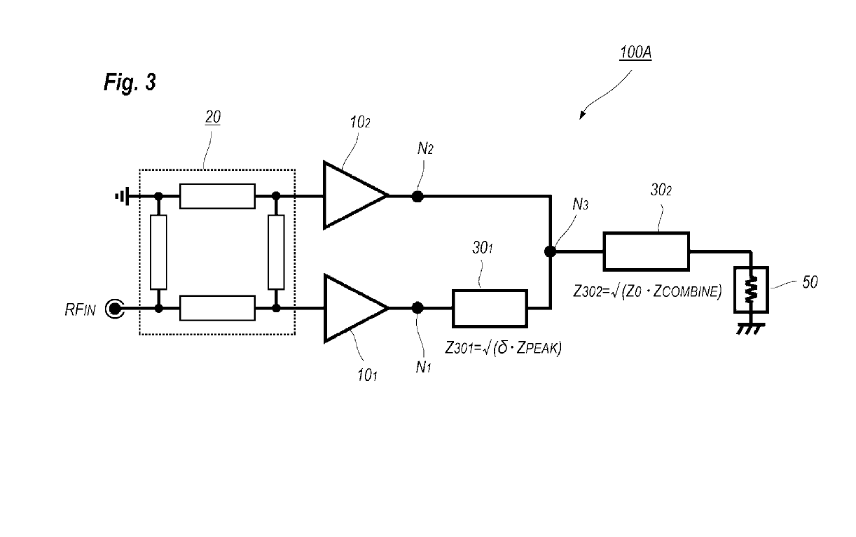

FIG. 3 shows a functional block diagram of one embodiment of a Doherty amplifier 100A according to the present invention, where the Doherty amplifier shown in FIG. 3 expands the back-off region to 8 dB based on the analysis described above. The Doherty amplifier 100A provides a hybrid coupler 20 as the input splitter. The hybrid coupler 20 may evenly provide an input RF signal RF_{IN} to the carrier amplifier 10₁ and the peak amplifier 10₂, where the RF signal provided to the peak amplifier 10₂ is delayed by 180° with respect to that provided to the input terminal of the Doherty amplifier 100A, while, the RF signal provided to the carrier amplifier 10₁ is also delayed but by 90° with respect to the RF signal at the input terminal. That is, the peak amplifier 10₂ receives the input RF signal delayed by 90 with respect to that received by the carrier amplifier 10₁.

The transmission line 30₁ provided in downstream the carrier amplifier 10₁ has the characteristic impedance of 61.5Ω, while, the transmission line 30₂ put between the combining node N₃ and the load 50 is set in the characteristic impedance thereof to be 38.8Ω. Setting the impedance of the load 50 to be 50Ω, the impedance seeing the load 50 at the combining node N₃ becomes 30.1Ω converted by the transmission line 30₂. In small input power where the peak amplifier 10₂ turns off, the carrier amplifier 10₁ may see the impedance at the node N₃ that is converted by the transmission line 30₁; that is, the impedance Z_{CARRIER} at the node N₁ becomes 61.5²/30.1=125.6Ω, which is greater than a value conventionally observed in the carrier amplifier 10₁. On the other hand, when both the carrier amplifier 10₁ and the peak amplifier 10₂ saturate, the load impedance of the both amplifiers, 10₁ and 10₂, is preferably set to be 50Ω, which means that the impedance Z_{CARRIER}′ seeing the carrier amplifier 10₁ at the combining node N₃ becomes 75.6Ω and the parallel impedance at the combining node N₃ becomes 30.1Ω that is preferably converted to the load impedance of 50Ω by the transmission line 30₂. Table 1 below summarizes various conditions for expanded OBOs when the load impedance Z₀ is 50Ω, and the load impedance Z_{PEAK}_{_}_{MAX} and the load impedance Z_{CARRIER}_{_}_{MAX} are also 50Ω when the carrier amplifier 10₁ and the peak amplifier 10₂ saturate. The conditions include the impedance of the two transmission lines, 30₁ and 30₂, the impedance Z_{COMBINE} at the combining node N₃ for the load impedance of 50Ω, load the impedance Z_{CARRIER}′ for the carrier amplifier 10₁ when the peak amplifier 10₂ turns off, and the impedance Z_{CARRIER} seeing the carrier amplifier 10₁ at the combining node N₃ when the peak amplifier 10₂ turns on. Table 2 also summarizes the conditions above described for the expanded OBO but when the load impedance Z_{CARRIER}_{_}_{MAX} of the carrier amplifier and the load impedance Z_{PEAK}_{_}_{MAX} of the peak amplifier when both are saturated are preferably set to be 60Ω.

TABLE 1

| OBO | | Z₃₀₁ | Z₃₀₂ | Z_{COMBINE} | Z_{CARRIER} | Z_{CARRIER}′ |
|---|---|---|---|---|---|---|
| (dBm) | δ | (Ω) | (Ω) | (Ω) | (Ω) | (Ω) |
| 7 | 1.24 | 55.7 | 37.2 | 27.7 | 111.9 | 61.9 |
| 8 | 1.51 | 61.5 | 38.8 | 30.1 | 125.6 | 75.6 |
| 9 | 1.82 | 67.4 | 40.2 | 32.3 | 140.9 | 90.9 |
| 10 | 2.16 | 73.5 | 41.4 | 34.2 | 158.1 | 105.1 |

Z₀ = 50 Ω,
Z_{PEAK}_{_{—}}_{MAX} = 50 Ω,
Z_{CARRIER}_{_{—}}_{MAX} = 50 Ω

TABLE 2

| OBO | | Z₃₀₁ | Z₃₀₂ | Z_{COMBINE} | Z_{CARRIER} | Z_{CARRIER}′ |
|---|---|---|---|---|---|---|
| (dBm) | δ | (Ω) | (Ω) | (Ω) | (Ω) | (Ω) |
| 7 | 1.24 | 66.8 | 40.7 | 33.2 | 134.3 | 74.3 |
| 8 | 1.51 | 73.8 | 42.5 | 36.1 | 150.7 | 80.7 |
| 9 | 1.82 | 80.9 | 44.0 | 38.7 | 169.1 | 109.1 |
| 10 | 2.16 | 88.2 | 45.3 | 45.3 | 189.7 | 129.7 |

Z₀ = 50 Ω,
Z_{PEAK}_{_{—}}_{MAX} = 60 Ω,
Z_{CARRIER}_{_{—}}_{MAX} = 60 Ω

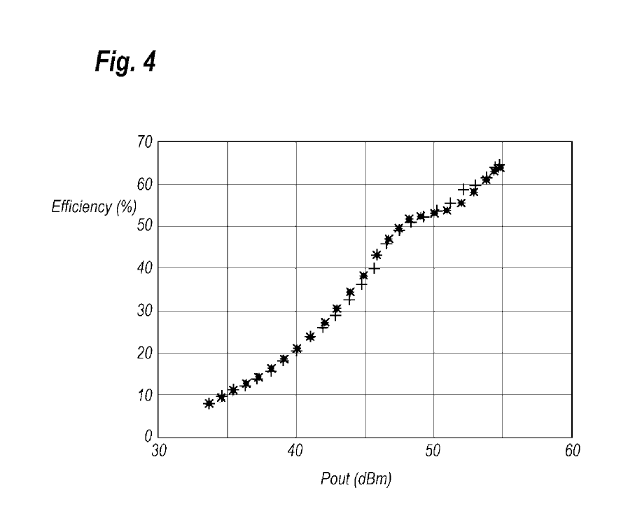

FIG. 4 shows a behavior of the efficiency of the Doherty amplifier shown in FIG. 3 against the output power Pout in the unit of decibel (dBm). The Doherty amplifier has the carrier amplifier 10₁ and the peak amplifier 10₂ symmetrical to each other, that is, both amplifiers, 10₁ and 10₂, implement a field effect transistor (FET) type of high electron-mobility transistor (HEMT) primarily made of gallium nitride (GaN). The Doherty amplifier implementing such FETs delivers maximum output power of 55.1 dBm (around 324 W) at 2.6 to 2.7 GHz, and the back-off of 8 dB, which means that only the carrier amplifier operates until the output power reaches 47.1 dBm (51.3 W), then the peak amplifier begins to operate with the total efficiency greater than 50%. Thus, the symmetrical Doherty amplifier 100A of the embodiment may be designed with additional headroom of 2 dB in the back-off range and an enhanced efficiency typically 10% greater than that of a conventional Doherty amplifier.

The Doherty amplifier 100A of the present embodiment provides the transmission lines in downstream the carrier amplifier 10₁ and in downstream the combining node N₃, but these transmission lines have the characteristic impedance greater than the load impedance Z₀and the load impedance divided by square root 2, Z₀/√2, which means that the carrier amplifier 10₁ saturates and the peak amplifier 10₂ begins to operate at the critical output power, which is more than 6 dB smaller than the maximum output power. That is, the back-off range from the critical output to the maximum output may be expanded more than 6 dB.

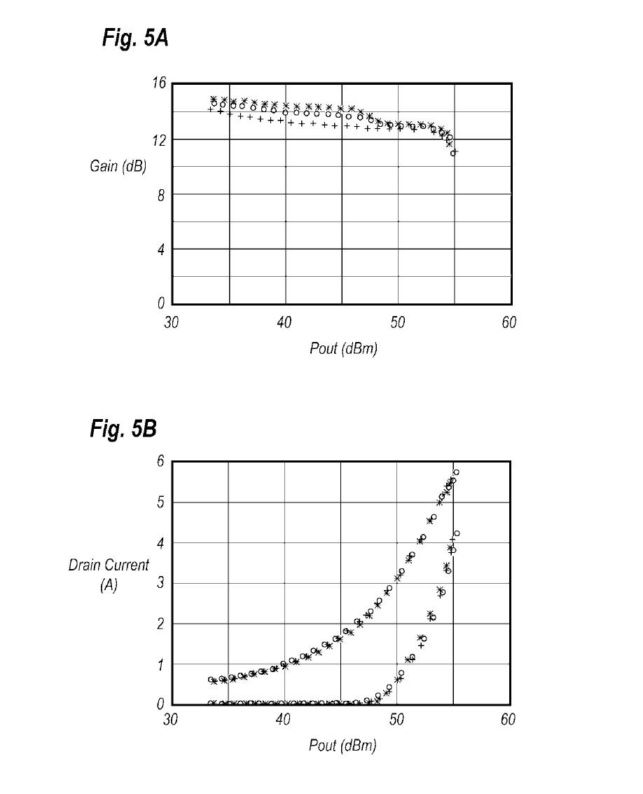

FIG. 5A shows the total gain of the Doherty amplifier 100A of FIG. 3 at 2.6 to 2.7 GHz. The back-off regions begins at 47.1 dBm as described above, but substantial no degradation in the total gain has been observed, and the total gain of 12 dB has been achieved at the maximum output power of 55.1 dB. FIG. 5B shows behaviors of the drain current of the FETs implemented within in the carrier amplifier and the peak amplifier also at 2.6 to 2.7 GHz. The drain current for the peak amplifier increases at the output power of 47.1 dBm, which is the beginning of the back-off region, but the drain current of the carrier amplifier gradually and continuously increases in the whole range of the output power.

While particular embodiment of the present invention have been described herein for purposes of illustration, many modifications and changes will become apparent to those skilled in the art. Accordingly, the appended claims are intended to encompass all such modifications and changes as fall within the true spirit and scope of this invention.

What is claimed is:

1. A Doherty amplifier that amplifies a radio frequency (RF) signal with a wavelength of λ and includes a carrier amplifier and a peak amplifier, the carrier amplifier operating in a whole range of output power of the Doherty amplifier, the peak amplifier operating in a back-off range of the output power, the Doherty amplifier comprising:
an input splitter that evenly splits the RF signal for the carrier amplifier and the peak amplifier, the RF signal provided to the peak amplifier being delayed by 90° with respect the RF signal provided for the carrier amplifier;
a first transmission line having one end connected to an output of the carrier amplifier and another end, the first transmission line having an electrical length of λ/4; and
a second transmission line having one end and another end, the second transmission line having an electrical length of λ/4, the one end of the second transmission line being connected to an output of the peak amplifier and the another end of the first transmission line, the another end of the second transmission line being connected to a load of the Doherty amplifier, the load having load impedance Z₀,
wherein the first transmission line has characteristic impedance greater than the load impedance Z₀, and the second transmission line has characteristic impedance greater than a value of the load impedance divided by square root of 2.

2. The Doherty amplifier according to claim 1,
wherein the Doherty amplifier has a back-off region greater than 6 dB.

3. The Doherty amplifier according to claim 1,
wherein the carrier amplifier and the peak amplifier show respective output impedance substantially same with each other when both the carrier amplifier and the peak amplifier saturate respective output power.

4. The Doherty amplifier according to claim 1,
wherein the input splitter is a type of hybrid coupler.

5. The Doherty amplifier according to claim 1,
wherein the input splitter is a type of transmission line having an electrical length of λ/4.

6. The Doherty amplifier according to claim 1,
wherein the carrier amplifier and the peak amplifier have a same configuration.

7. The Doherty amplifier according to claim 6,
wherein the carrier amplifier and the peak amplifier implement field effect transistors type of high electron-mobility transistor as an amplifying device.
